(19) United States
(12) Patent Application Publication
(10) Pub. No.: US 2025/0219006 A1
(43) Pub. Date: Jul. 3, 2025

(54) Semiconductor Device and Method of Making a Chip-on-Wafer Underfill Barrier

(71) Applicant: STATS ChipPAC Pte. Ltd., Singapore (SG)

(72) Inventors: Marites Roque, Singapore (SG); Linda Pei Ee Chua, Singapore (SG); Rowena Zarate, Singapore (SG); Yi Jing Eric Chong, Singapore (SG); Kai Chong Chan, Singapore (SG)

(73) Assignee: STATS ChipPAC Pte. Ltd., Singapore (SG)

(21) Appl. No.: 18/403,288

(22) Filed: Jan. 3, 2024

(51) Int. Cl. H01L 23/00; H01L 23/498; H01L 25/00; H01L 25/065; H05K 1/18

(52) U.S. Cl. CPC H01L 24/32; H01L 23/49811; H01L 23/49838; H01L 24/08; H01L 24/16; H01L 24/73; H01L 25/0657; H01L 25/50; H01L 2224/08225; H01L 2224/16227; H01L 2224/16238; H01L 2224/32225; H01L 2224/73204; H01L 2924/15321; H05K 1/181

(57) ABSTRACT

A semiconductor device has a first semiconductor die and a first insulating layer formed over the first semiconductor die. A trench is formed in the first insulating layer. A second insulating layer is formed over the first insulating layer. A recess forms in the second insulating layer over the trench automatically as part of the formation process of the second insulating layer. A second semiconductor die is mounted over the second insulating layer. The recess completely surrounds the second semiconductor die in plan view. An underfill is dispensed between the first semiconductor die and second semiconductor die.

### FIELD OF THE INVENTION

The present invention relates in general to semiconductor devices and, more particularly, to a semiconductor device and method of making a chip-on-wafer underfill barrier.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, power conversion, photo-electric, and creating visual images for television displays. Semiconductor devices are found in the fields of communications, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. When multiple semiconductor die are to be packaged together, one method of shrinking the end device is to mount the smaller die directly on the semiconductor wafer of the larger die. This is known as chip-on-wafer (CoW).

CoW requires underfill dispensing in a tight and narrow gap between the edges of the smaller die and solder bumps on the active surface of the larger die. At the same time, the realities of CoW devices mean that 100% underfill coverage is required on all sides and corners of the smaller die. This requirement poses a challenge for the underfill process due to the risk of underfill overflowing the intended area and bridging the surrounding solder bumps, which will lead to reduced yield and reliability. Therefore, a need exists for an improved chip-on-wafer device and manufacturing process.

### BRIEF DESCRIPTION OF THE DRAWINGS

FIGS. 1a-1c illustrate a semiconductor wafer with a plurality of semiconductor die separated by a saw street;

FIGS. 2a-2m illustrate forming a trench barrier to impede underfill spread on a CoW in a first embodiment;

FIGS. 3a-3e illustrate forming a trench barrier to impede underfill spread on a CoW in a second embodiment;

FIGS. 4a-4f illustrate forming a dam barrier to impede underfill spread on a CoW in a third embodiment; and

FIGS. 5a and 5b illustrate integrating the CoW devices into a larger electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices. The terms “semiconductor die” and “die” are synonymous. The terms “semiconductor wafer” and “wafer” are synonymous.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the semiconductor package. The electrical connections can be made with conductive layers, bumps, stud bumps, conductive paste, or wirebonds. An encapsulant or other molding material is deposited over the semiconductor package to provide physical support and electrical isolation. The finished semiconductor package is then inserted into an electrical system and the functionality of the semiconductor device is made available to the other system components.

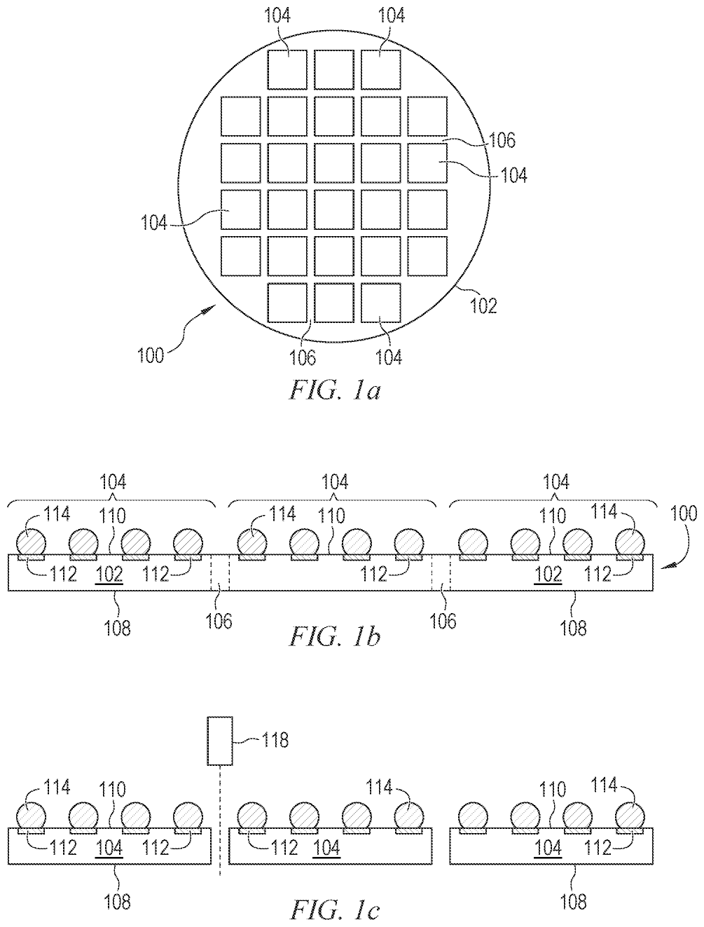

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuit (ASIC), memory, power device, or other signal processing circuit. Semiconductor die 104 may also contain integrated passive devices (IPDs), such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form bumps 114. In one embodiment, bump 114 is formed over an under-bump metallization (UBM) having a wetting layer, barrier layer, and adhesion layer. Bump 114 can also be compression bonded or thermocompression bonded to conductive layer 112.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

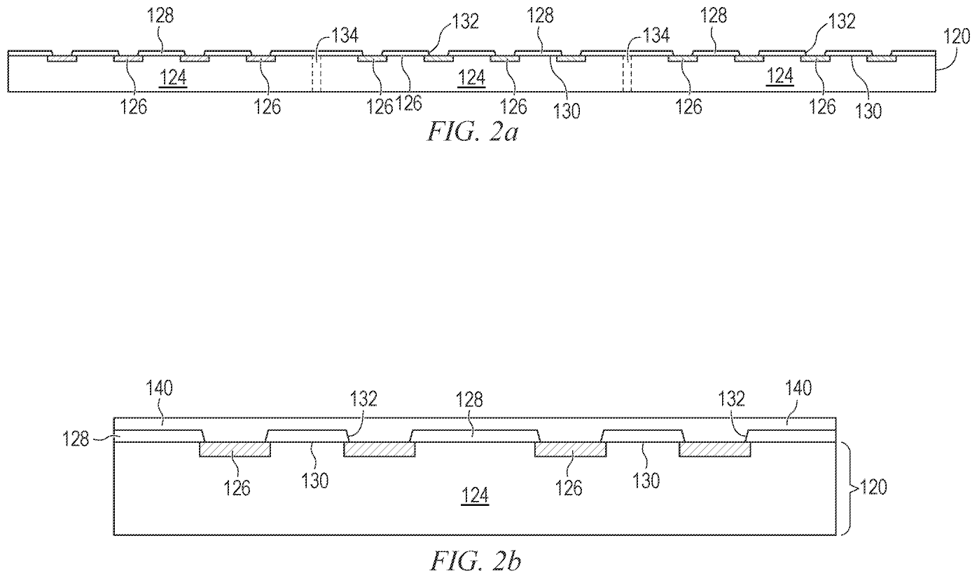

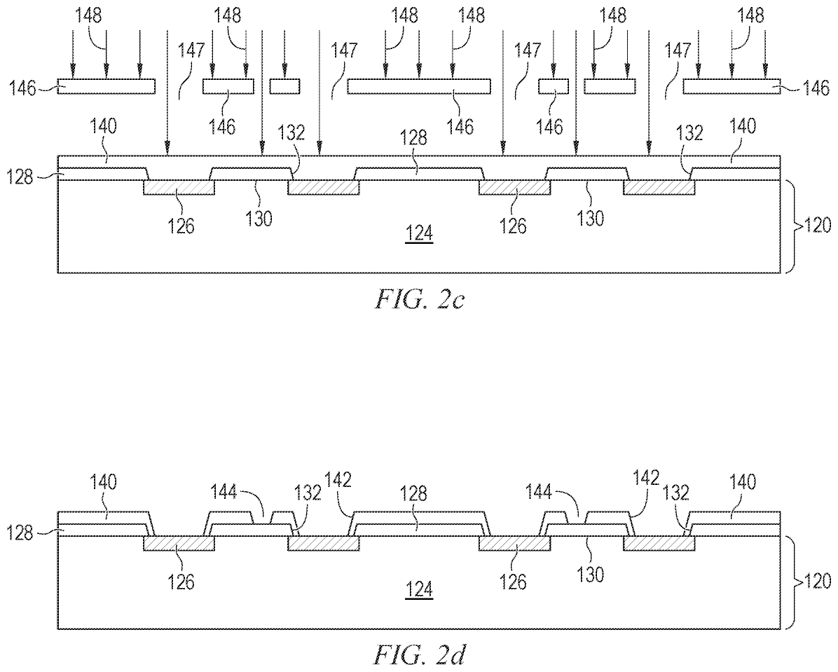

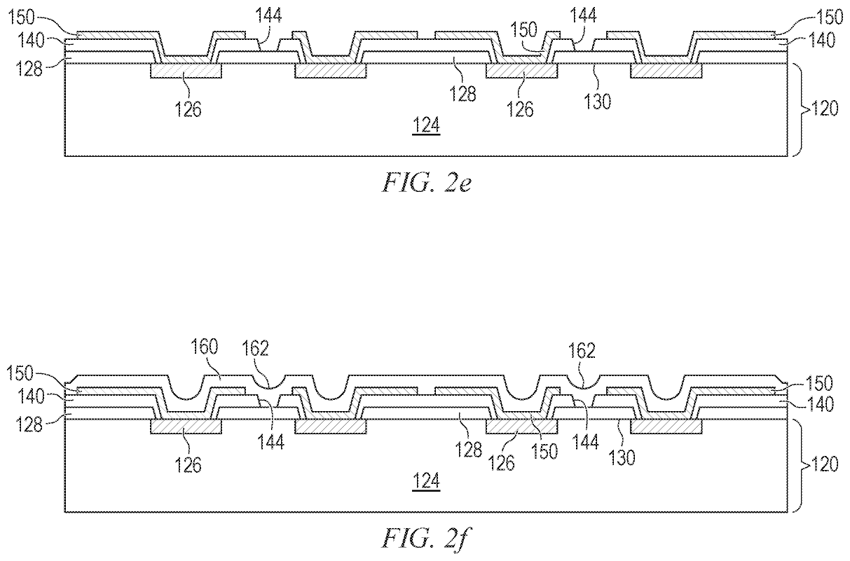

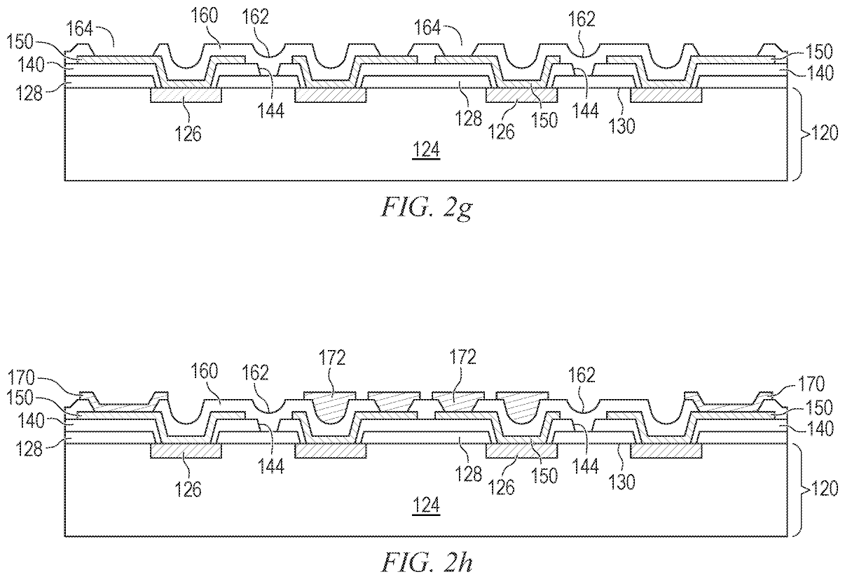

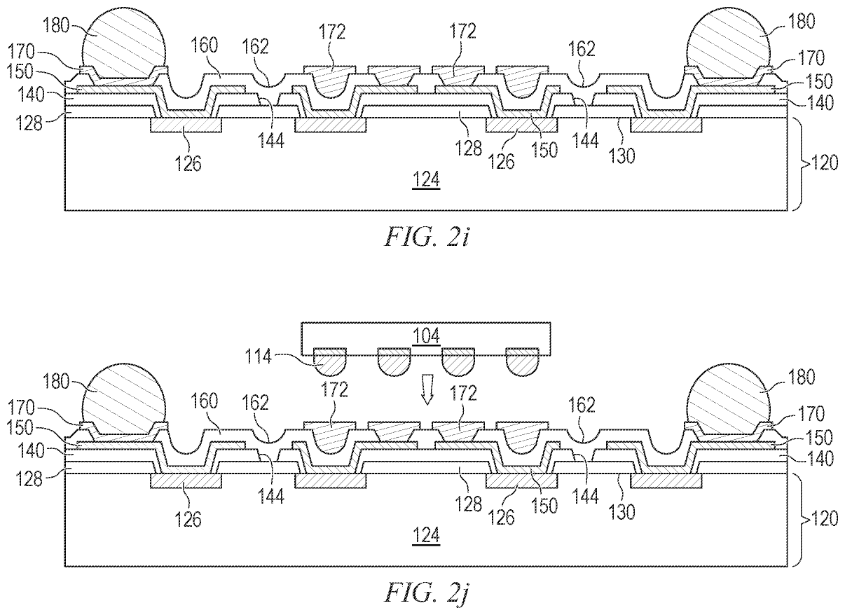

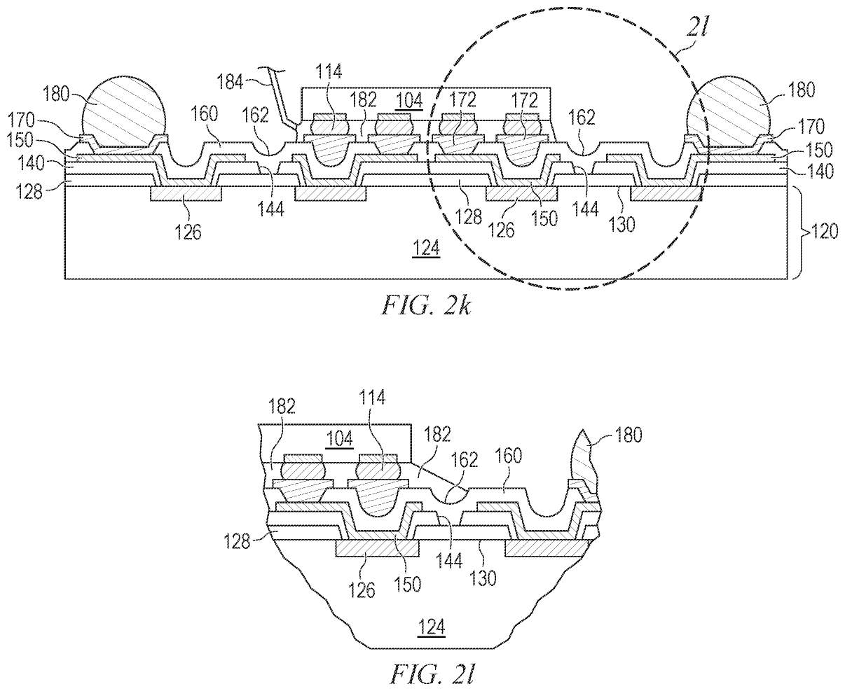

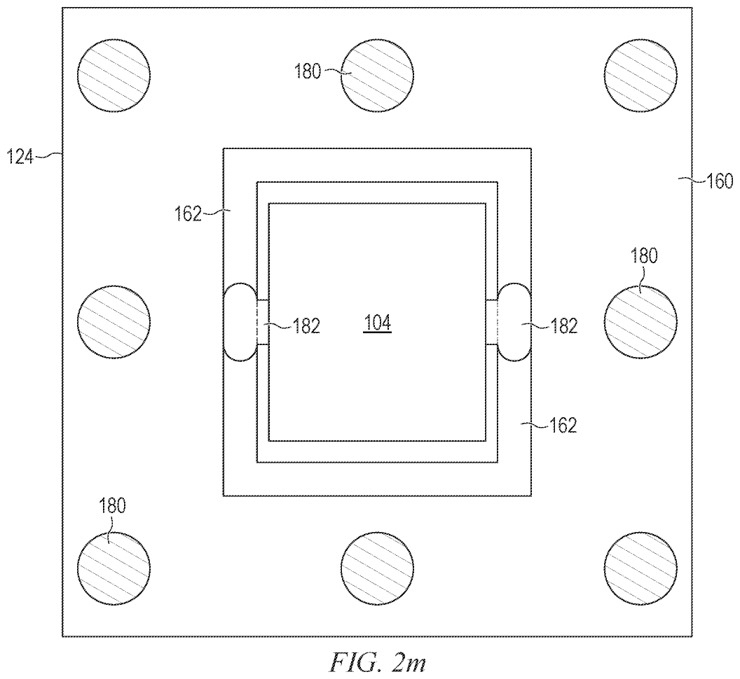

FIGS. 2a-2m illustrate forming a chip-on-wafer (CoW) module with semiconductor die 104. FIG. 2a shows a partial cross-section of semiconductor wafer 120, which will be the CoW wafer while semiconductor die 104 will be the CoW chip. Semiconductor wafer 120 is similar to semiconductor wafer 100, e.g., formed of similar materials with active and passive electrical components formed within semiconductor die 124, but generally larger. Semiconductor die 124 includes contact pads 126 formed and functioning similarly to contact pads 112 of semiconductor die 104.

A passivation layer 128 is formed over active surface 130 of semiconductor wafer 120. Passivation layer 128 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Passivation layer 128 can be formed using PVD, CVD, printing, lamination, spin coating, spray coating, sintering, thermal oxidation, or another suitable method. Passivation layer 128 provides a protective coating for active surface 130 and contact pads 126 during handling and processing of semiconductor wafer 120 between the manufacturing steps used to form electrical circuits in the active surface and the following illustrated and described manufacturing steps. Any insulating, dielectric, or passivation layer described above or below can be formed using any of the materials or methods described for passivation layer 128.

Openings 132 are formed through passivation layer 128 to expose contact pads 126 and allow electrical connection by a conductive layer to be subsequently formed. Openings 132 are formed by laser ablation, chemical etching, mechanical drilling, photolithography, or another suitable method.

From FIG. 2b onward, only a single semiconductor die 124 is illustrated to provide greater detail of the processes being performed. However, all of the illustrated steps occur at the wafer level prior to singulation through saw streets 134 to separate the die 124 from each other. A semiconductor wafer 120 can include tens, hundreds, or even thousands of semiconductor die 124 all processed at once using the following steps, shown for only a single semiconductor die, performed en masse.

In FIG. 2b, a dielectric layer 140 is formed over active surface 130 and passivation layer 128. Dielectric layer 140 is deposited to extend into and completely fill openings 132 of passivation layer 128, as well as completely cover up the top surface of the passivation layer. Dielectric layer 140 completely covers the entire footprint of wafer 120. Dielectric layer 140 is formed in a similar process and of similar materials as described above for passivation layer 128.

FIG. 2c shows a mask 146 disposed over dielectric layer 140. In the illustrated embodiment, dielectric layer 140 is a photolithography layer, so light rays 148 going through openings 147 of mask 146 modifies the molecular structure of the dielectric layer. When dielectric layer 140 is developed and washed away in FIG. 2d, openings 142 and trench 144 are formed through the dielectric layer. In some embodiments, openings 142 and trench 144 are both formed completely through dielectric layer 140 without extending into contact pads 126 or passivation layer 128.

Openings 142 are formed through the dielectric layer to expose contact pads 126 without exposing passivation layer 128. Openings 142 are approximately concentric with openings 132 of passivation layer 128 such that each of the openings 142 extends through a respective opening 132. In other embodiments, openings 132 are not previously formed, and openings 142 are formed through both dielectric layer 140 and passivation layer 128 in a single processing step. Openings 142 can be formed as described above for openings 132.

Trench 144 follows a continuous path completely surrounding the area where semiconductor die 104 will be mounted, as shown below in FIG. 2m for recess 162. In other embodiments, trench 144 is only formed in areas where the potential for underfill seeping out to solder bumps is of concern. Trench 144 can be formed as described above for opening 132, e.g., chemical etching, mechanical etching, or laser ablation. In one embodiment, passivation layer 128 operates as an etch-stop layer for an etching process used to form both openings 142 and trench 144 at the same time. The material of passivation layer 128 stops the etching process from extending below dielectric layer 140 for trenches 144 while openings 142 are etched all the way down to contact pads 126. In a laser ablation embodiment, openings 142 can be formed at a greater laser output power or duration than trench 144 to extend deeper. In other embodiments, trenches 144 extend into or completely through passivation layer 128.

A conductive layer 150 is formed over dielectric layer 140 in FIG. 2e. Conductive layer 150 is formed of the materials and using the methods described above for conductive layer 112. Conductive layer 150 is formed completely covering the exposed top surfaces of contact pads 126, passivation layer 128, and dielectric layer 140, and then patterned as illustrated. Conductive layer 150 is patterned to include conductive vias extending down into openings 142 to physically and electrically connect to contact pads 126. Conductive layer 150 can be a conformal layer as illustrated or completely fill the space of openings 142. Conductive layer 150 is also patterned to include conductive traces fanning out from contact pads 126 across active surface 130. Conductive layer 150 optionally includes contact pads where overlying conductive layers will be connected.

In some embodiments, the electrical circuits of semiconductor die 124 are laid out such that contact pads of conductive layer 126 that are to be connected to semiconductor die 104 are all located within the boundary formed by trench 144 and all contact pads for external interconnect are located outside of the trench. That allows conductive layer 150 to be patterned with no conductive traces being required to cross trench 144. In other embodiments, conductive traces of conductive layer 150 are formed across trench 144. Conductive layer 150 is thin enough to be formed within trench 144 without critically impacting the intended functionality of the trench.

In FIG. 2f, an insulating layer 160 is formed over conductive layer 150 and into trench 144, including completely filling up the trench. Insulating layer 150 is formed of the materials and using the methods described above for passivation layer 128. Insulating layer 160 completely covers the entire footprint of wafer 120. Insulating layer 160 is a conformal layer that follows the contours of the underlying layers, e.g., the conductive vias of conductive layer 150 and trench 144. Insulating layer 160 is formed thinner than insulating layer 140 in some embodiments to ensure that the top surface of insulating layer 160 conforms to the underlying contours. In one embodiment, insulating layer 140 is twenty μm thick while insulating layer 150 is ten μm thick.

The top surface of insulating layer 160 over the trench forms a recess 162 in insulating layer 160. Recess 162 is caused as a result of insulating layer 160 being formed on trench 144, and therefore follows the same path as the trench and forms a continuous circuit around the intended location for mounting semiconductor die 104. When initially formed, insulating layer 160 follows the topology of trench 144, thus creating recess 162 automatically during the formation or deposition process of the insulating layer.

In FIG. 2g, openings 164 are formed through insulating layer 160 to expose underlying contact pads of conductive layer 150. Openings 164 are formed as described above for openings 132, e.g., chemical etching or laser ablation.

In FIG. 2h, a conductive layer 170-172 is formed over insulating layer 160 and into openings 164. In one embodiment, openings 164 outside of recess 162 have under-bump metallization (UBM) 170 formed as contact pads for large solder bumps to be disposed on in a later step, while openings 164 encircled by recess 162 are smaller and configure to mount die 104. UBM 170 can be formed in a separate manufacturing step from contact pads 172 if different material composition or finishes are desired. In another embodiment, the conductive material for both UBM 170 and contact pads 172 is deposited over an entire footprint of wafer 120 and then patterned as illustrated. Both UBM 170 and contact pads 172 can include a wetting layer, a barrier layer, and an adhesion layer. Conductive traces can be formed if redistribution is needed to fan-out or fan-in from contact pads of conductive layer 150 to the final location desired for connection to semiconductor die 104. Conductive layer 170-172 follows the contours of insulating layer 160. Therefore, UBM 170 and contact pads 172 may be more desirably formed outside of the footprints of contact pads 126.

In FIG. 2i, solder bumps 180 are formed on UBM 170 as described above for bumps 114 on conductive layer 112 of semiconductor die 104. Bumps 180 are bigger than bumps 114 and should be made at least tall enough to extend over the back surface of semiconductor die 104 once the smaller semiconductor die is mounted on contact pads 172. In some embodiments, the layout of wafer 120 is such that recess 162 is disposed within 30-50 μm of bumps 180.

Semiconductor die 104 is mounted onto contact pads 172 in FIG. 2j by picking and placing the smaller semiconductor die over semiconductor die 124 and lowering semiconductor die 104 so that bumps 114 rest on the contact pads. Bumps 114 are reflowed to mechanically attach and electrically connect semiconductor die 104 to semiconductor die 124. Semiconductor die 104 is electrically connected to semiconductor die 124 through bumps 114, contact pads 172, and conductive layer 150.

In FIG. 2k, an underfill 182 is dispensed into the gap remaining between semiconductor die 104 and semiconductor die 124 after the smaller semiconductor die is mounted. Underfill 182 can be an epoxy resin, epoxy acrylate, any of the materials described above for passivation layer 128, a polymer composite, or another suitable polymer. Underfill 182 is deposited as a liquid using a nozzle 184 located at one point along the perimeter of semiconductor die 104. Capillary action distributes the underfill 182 from nozzle 184 to fill the footprint of semiconductor die 104.

Due to the small size of semiconductor die 104 and the tight lateral spacing between semiconductor die 104 and solder bumps 180, accurately dispensing underfill 182 can be a challenge. Underfill 182 can easily spread out beyond the footprint of semiconductor die 104 inadvertently, as shown in the detailed view of FIG. 2l. When some underfill 182 leaks out from under semiconductor die 104, the underfill flows into recess 162 and along the length of the recess parallel to the edge of the semiconductor die. Recess 162 blocks underfill 182 from continuing to flow perpendicular to the edge of semiconductor die 104 to reach solder bump 180, which would have the potential to cause malfunction in the final device. Underfill 182 flows along recess 162 rather than flowing up the opposite edge of the recess to reach bumps 182. Recess 162 is formed continuously around a single semiconductor die to prevent underfill flowing from the semiconductor die to an adjacent solder bump. Recess 162 protects bumps 180.

FIG. 2m shows a plan view to illustrate how recess 162 extends completely around semiconductor die 104 so that underfill 182 is captured by the recess no matter in which direction the underfill inadvertently flows away from the smaller semiconductor die. In other embodiments, trench 144, and therefore recess 162, is formed only in select locations between die 104 and bumps 180 without completely surrounding die 104. Underfill 182 reaches recess 162 and then flows laterally within the recess instead of continuing to flow toward bump 180. The addition of recess 162, formed using a trench 144 in an underlying insulating layer, provides a wider process margin for the underfill process in CoW applications. The likelihood of underfill 182 touching a solder bump 180 or even bridging together two solder bumps 180 is greatly reduced, thus increasing yield and reducing malfunctions in the final devices being formed.

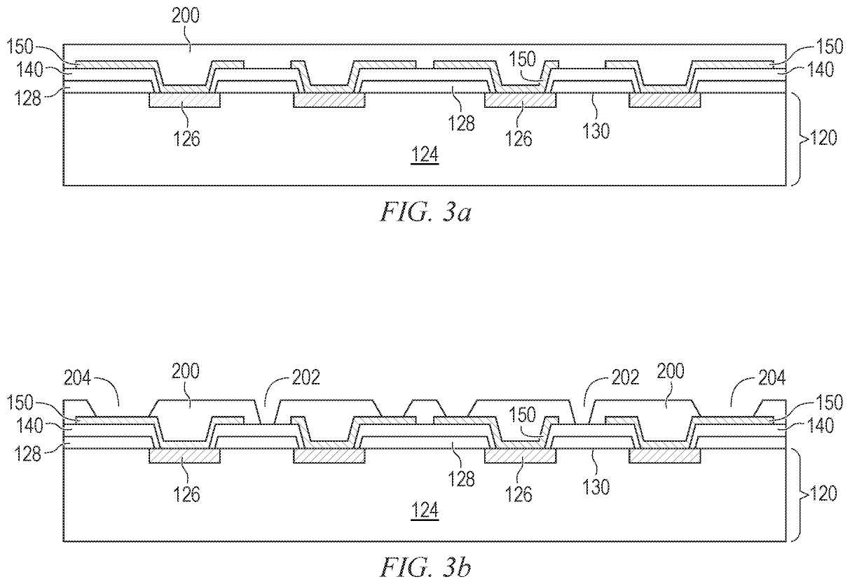

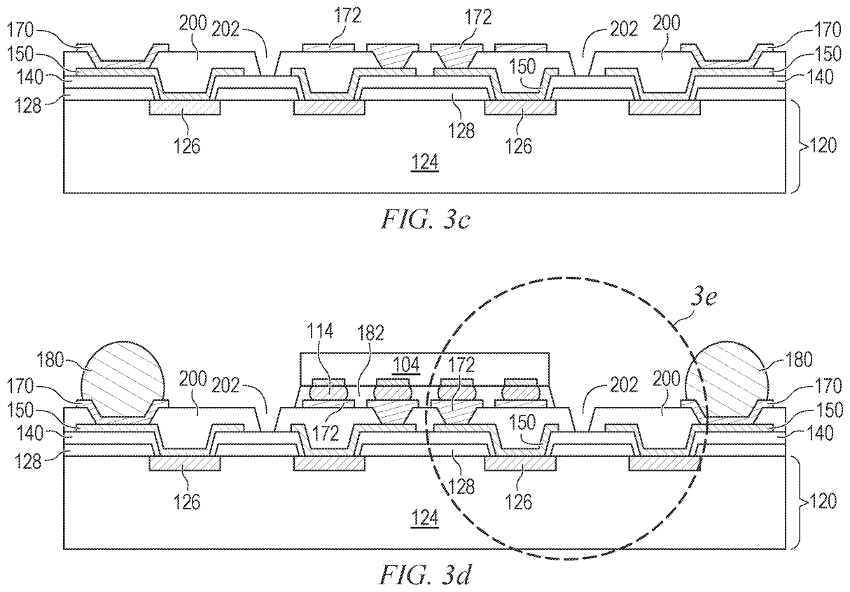

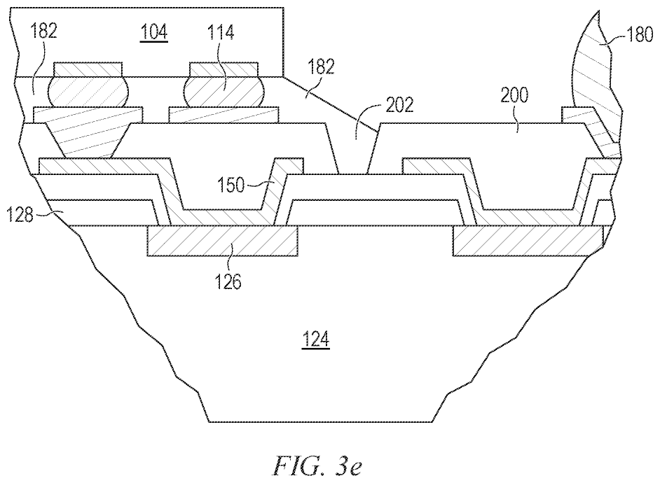

FIGS. 3a-3e illustrate an alternative embodiment where a trench is formed directly in the top insulating layer rather than a trench in dielectric layer 140 resulting in a recess in the top insulating layer. FIG. 3a continues from FIG. 2e, except without trenches 144 having been formed in dielectric layer 140. An insulating layer 200 is formed over dielectric layer 140 and conductive layer 150. Insulating layer 200 is substantially the same as insulating layer 160, except that, in the absence of trenches 144, no recess forms in the top surface of insulating layer 200 as with recess 162. Insulating layer 200 has a planar top surface across the entire footprint of wafer 120.

In FIG. 3b, trench 202 and openings 204 are formed in or through insulating layer 200. Trench 202 is formed in a similar manner to trench 144, and, like trench 144, trench 202 follows a path that surrounds the intended mounting location for semiconductor die 104. Openings 204 are formed through insulating layer 200 to expose contact pads of conductive layer 150 for subsequent electrical connection. Openings 204 and 202 are formed in a single etching step in some embodiments, similar to the method shown above in FIG. 2c using mask 146. In FIG. 3c UBM 170 and contact pads 172 are formed as described above. Contact pads 172 for mounting semiconductor die 104 are located within and completely surrounded in plan view by trench 202.

FIG. 3d shows semiconductor die 104 mounted on contact pads 172 and underfill 182 applied between semiconductor die 104 and 124. The detailed view of FIG. 3e shows how trench 202 captures underfill 182 that overflows away from semiconductor die 104 before the underfill can reach and possibly bridge conductive bumps 180. Underfill 182 flows laterally in trench 202, parallel to the edge of semiconductor die 104, rather than continuing to flow toward bumps 180. Trench 202 is formed continuously around a single semiconductor die to prevent underfill flowing from the semiconductor die to an adjacent solder bump. Trench 202 protects bumps 180.

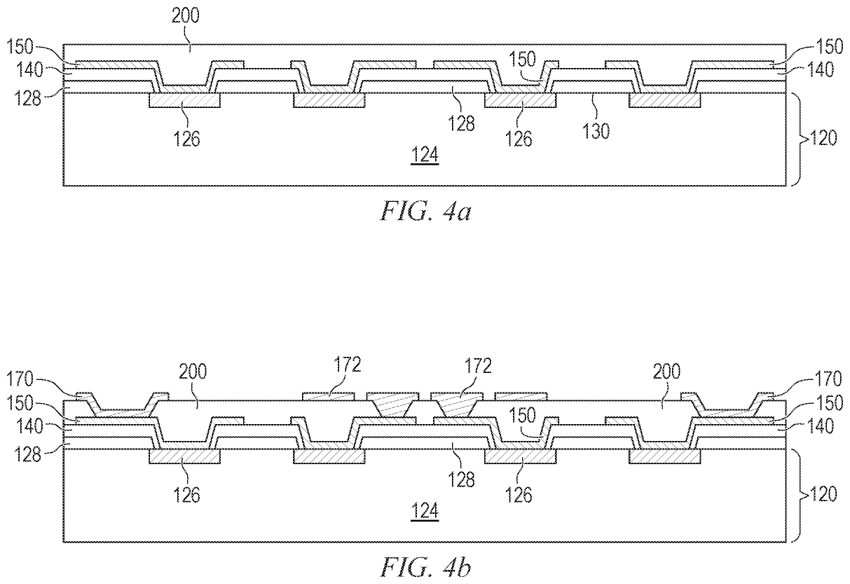

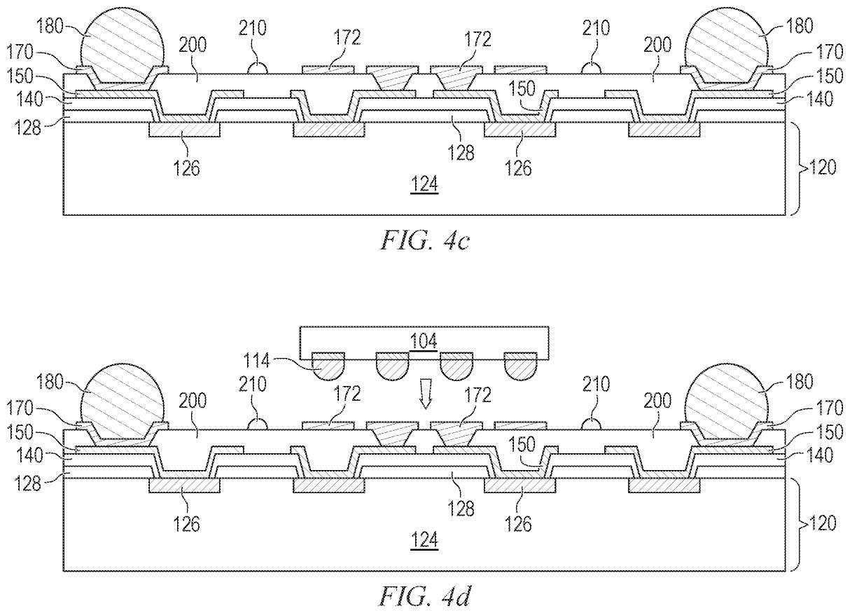

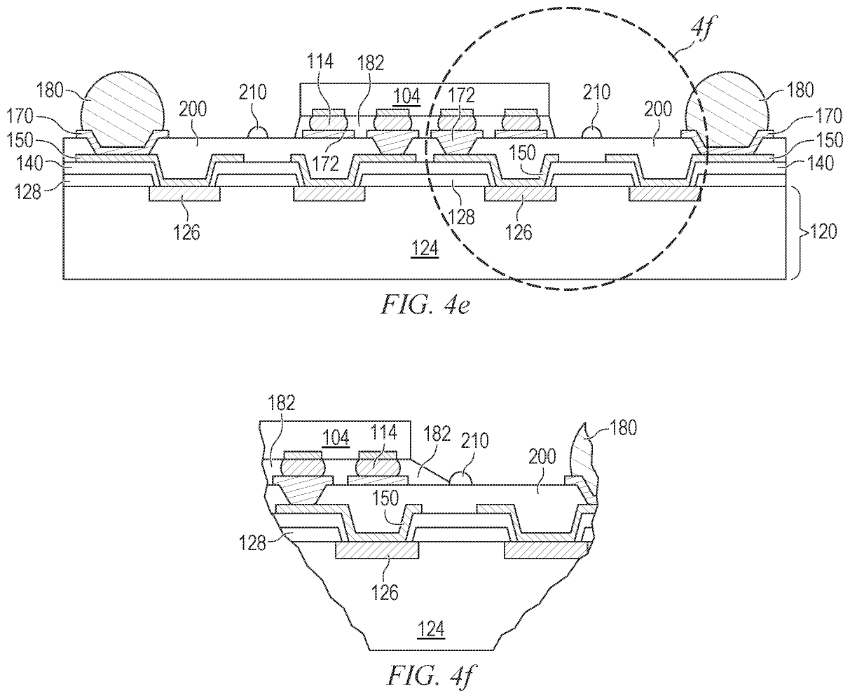

FIGS. 4a-4f illustrate another embodiment with a dam used to block flow of underfill rather than a trench. FIG. 4a shows insulating layer 200 formed over dielectric layer 140 and conductive layer 150 as in FIG. 3a. In FIG. 4b, UBM 170 and contact pads 172 are formed as described above. In FIG. 4c, bumps 180 are formed on UBM 170. A dam 210 is formed on insulating layer 200 around the mounting location for semiconductor die 104. Dam 210 is formed directly on the insulating layer of a substrate, rather than requiring, e.g., contact pads or other processing on the surface of the substrate prior to forming the dam. Dam 210 can therefore be formed in any substrate design without requiring a pre-defined dispensing area.

Dam 210 can be formed before or after formation of bumps 180. Dam 210 follows the same or a similar path as trenches 144 and 202 in plan view to surround the intended mounting location of semiconductor die 104. Dam 210 is formed of a glob top material or liquid epoxy that does not have resin bleedout and dispensed using a nozzle, similar to nozzle 184, that moves in the desired path for the dam while dispensing insulating material. In some embodiments, a non-conductive material without resin is used.

In FIG. 4d, semiconductor die 104 is mounted on contact pads 172. Dam 210 completely surrounds semiconductor die 104 in plan view. Dam 210 is formed between 30 and 50 microns (μm) away from the edge of solder bump 180. In some embodiments, dam 210 is formed after flip-chip attach of semiconductor die 104. The height of dam 210 is lower than the height of semiconductor die 104 over wafer 120.

Underfill 182 is dispensed in FIG. 4e as described above. FIG. 4f shows a detailed view of some underfill 182 leaking out toward bumps 180. Underfill 182 flows to dam 210 and is contained by the dam. Dam 210 stops the flow of underfill 182 before the underfill reaches bumps 180, which would potentially bridge two bumps and increase the likelihood of malfunction. Dam 210 is formed continuously around a single semiconductor die to prevent underfill flowing from the semiconductor die to an adjacent solder bump. Dam 210 protects bumps 180.

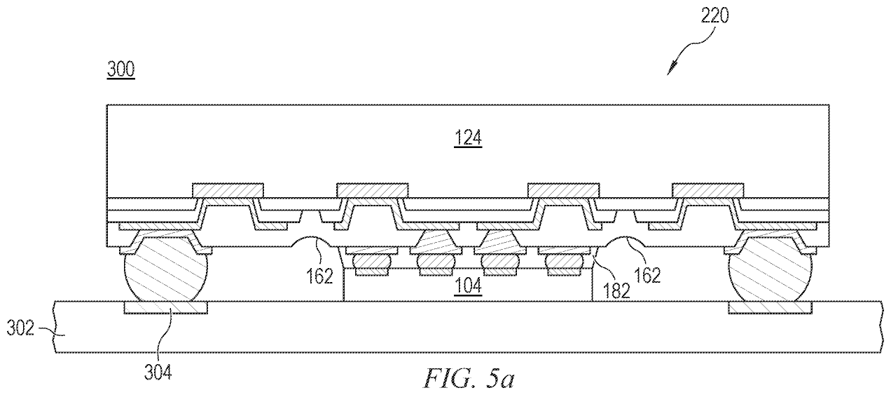

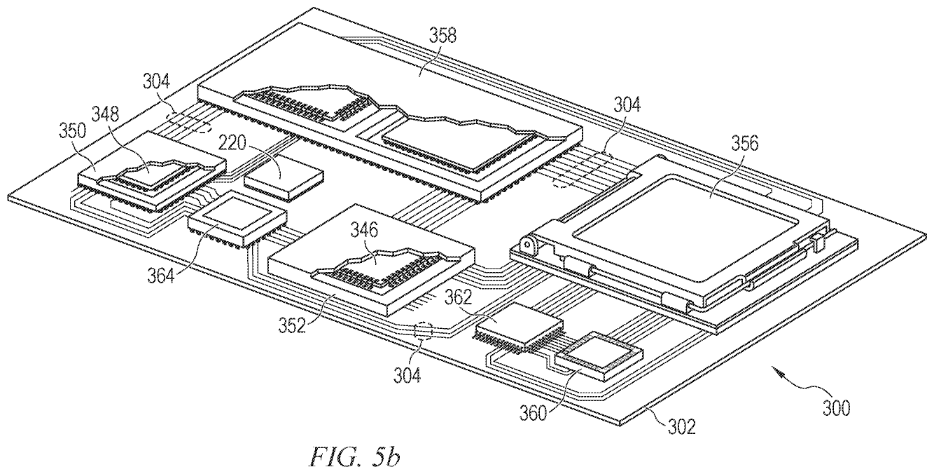

FIGS. 5a and 5b illustrate integrating the above-described CoW modules, e.g., CoW module 220, into a larger electronic device 300. CoW module 220 in FIG. 5a is formed by singulating wafer 120 through saw streets 134 after completing one of the processes shown or described above. Singulation can be done by saw blade, laser cutting tool, or another appropriate tool. A protective molding, encapsulant, insulating material, or insulating layer is optionally deposited over the top and side surfaces of semiconductor die 124.

FIG. 5a illustrates a partial cross-section of CoW module 220 mounted onto a printed circuit board (PCB) or other substrate 302 as part of electronic device 300. Bumps 180 are reflowed onto conductive layer 304 of PCB 302 to physically attach and electrically connect CoW module 220 to the PCB. In other embodiments, thermocompression or another suitable attachment and connection methods are used. In some embodiments, an adhesive or underfill layer is used between CoW module 220 and PCB 302. Semiconductor die 104 is electrically coupled to semiconductor die 124 through bumps 114, contact pads 172, and conductive layer 150. Semiconductor die 124 is electrically coupled to conductive layer 304 through conductive layer 150, UBM 170, and bumps 180. Semiconductor die 104 is indirectly coupled to conductive layer 304 through semiconductor die 124. In other embodiments, where conductive layer 150 optionally bridges trench 144, semiconductor die 104 can be directly coupled to conductive layer 304 through conductive layer 150. Semiconductor die 104 may physically contact PCB 302, or a gap may be present.

FIG. 5b illustrates electronic device 300 having a chip carrier substrate or PCB 302 with a plurality of semiconductor packages disposed on a surface of PCB 302, including CoW module 220. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first semiconductor die;
forming a first insulating layer over the first semiconductor die;
forming a trench in the first insulating layer;
forming a second insulating layer over the first insulating layer, wherein a recess forms in the second insulating layer over the trench automatically as part of the formation process of the second insulating layer;
mounting a second semiconductor die over the second insulating layer, wherein the recess completely surrounds the second semiconductor die in plan view; and
dispensing an underfill between the first semiconductor die and second semiconductor die.

2. The method of claim 1, wherein a portion of the underfill flows into the recess.

3. The method of claim 1, further including dispensing the underfill to completely fill a footprint of the second semiconductor die.

4. The method of claim 1, further including forming a first conductive layer between the first insulating layer and second insulating layer.

5. The method of claim 4, further including forming a second conductive layer over the second insulating layer, wherein the first semiconductor die is electrically coupled to the second semiconductor die through the first conductive layer and second conductive layer.

6. The method of claim 5, further including forming a solder bump on the second conductive layer outside a boundary formed by the recess.

7. A method of making a semiconductor device, comprising:
providing a first semiconductor die;
forming a barrier over the first semiconductor die;
disposing a second semiconductor die over the first semiconductor die, wherein the barrier extends completely around the second semiconductor die; and
dispensing an underfill between the first semiconductor die and second semiconductor die.

8. The method of claim 7, further including forming the barrier by:
forming a first insulating layer over the first semiconductor die; and
forming a trench in the first insulating layer.

9. The method of claim 8, further including forming the barrier by forming a second insulating layer over the first insulating layer, wherein a recess is formed in the second insulating layer over the trench automatically as part of the process of forming the second insulating layer.

10. The method of claim 7, further including forming the barrier by dispensing an insulating material to form a dam.

11. The method of claim 7, further including:
forming a conductive layer over the first semiconductor die;
forming a contact pad over the conductive layer; and
mounting the second semiconductor die to the contact pad.

12. The method of claim 11, further including:
forming an under-bump metallization over the first semiconductor die outside a boundary of the barrier; and
disposing a solder bump on the under-bump metallization.

13. The method of claim 7, further including dispensing the underfill to completely fill a footprint of the second semiconductor die.

14. A semiconductor device, comprising:
a first semiconductor die;
a first insulating layer formed over the first semiconductor die;
a trench formed in the first insulating layer;
a second insulating layer formed over the first insulating layer including a recess in the second insulating layer over the trench;
a second semiconductor die mounted over the second insulating layer, wherein the recess completely surrounds the second semiconductor die in plan view; and
an underfill dispensed between the first semiconductor die and second semiconductor die.

15. The semiconductor device of claim 14, wherein the underfill extends into the recess.

16. The semiconductor device of claim 14, wherein the underfill completely fills a footprint of the second semiconductor die.

17. The semiconductor device of claim 14, further including a first conductive layer formed between the first insulating layer and second insulating layer.

18. The semiconductor device of claim 17, further including a second conductive layer formed over the second insulating layer, wherein the first semiconductor die is electrically coupled to the second semiconductor die through the first conductive layer and second conductive layer.

19. The semiconductor device of claim 18, further including a solder bump formed on the second conductive layer outside a boundary formed by the recess.

20. A semiconductor device, comprising:
a first semiconductor die;
a barrier formed over the first semiconductor die;
a second semiconductor die disposed over the first semiconductor die, wherein the barrier extends completely around the second semiconductor die; and
an underfill dispensed between the first semiconductor die and second semiconductor die.

21. The semiconductor device of claim 20, further including:
a first insulating layer formed over the first semiconductor die; and
a trench formed in the first insulating layer.

22. The semiconductor device of claim 21, further including a second insulating layer formed over the first insulating layer with a recess in the second insulating layer over the trench.

23. The semiconductor device of claim 20, wherein the barrier includes a dam formed of an insulating material.

24. The semiconductor device of claim 20, further including:
a conductive layer formed over the first semiconductor die; and
a contact pad formed over the conductive layer, wherein the second semiconductor die is mounted to the contact pad.

25. The semiconductor device of claim 24, further including:
an under-bump metallization formed over the first semiconductor die outside a boundary of the barrier; and
a solder bump disposed on the under-bump metallization.
